(19) United States
(12) Patent Application Publication
(10) Pub. No.: US 2024/0104284 A1
(43) Pub. Date: Mar. 28, 2024

(54) FEATURE BASED CELL EXTRACTION FOR PATTERN REGIONS

(71) Applicant: ASML NETHERLANDS B.V., Veldhoven (NL)

(72) Inventor: Yan-ting LIN, Shenzhen City, Guangdong Province (CN)

(73) Assignee: ASML NETHERLANDS B.V., Veldhoven (NL)

(21) Appl. No.: 18/039,701

(22) PCT Filed: Nov. 24, 2021
(86) PCT No.: PCT/EP2021/082880

§ 371 Date: May 31, 2023

(30) Foreign Application Priority Data
Dec. 21, 2020 (WO) PCT/CN2020/137957

(51) Int. Cl. G06F 30/392; G06F 30/398

(52) U.S. Cl. CPC G06F 30/392; G06F 30/398

(57) ABSTRACT

Systems and methods of feature-based cell extraction. The methods include obtaining data representative of a layout, wherein the layout includes a pattern region having no vertices, extracting unit cells from the pattern region having no vertices, identifying, using the unit cells, a set of regions of the layout matching the unit cells, and generating, using the unit cells, a hierarchy for the set of regions. In some embodiments the pattern regions have oblique angle features or have no vertices of features. The pattern regions can have a feature including a feature slope, a horizontal or a vertical pitch, or a line-space feature. In some embodiments the hierarchy is optimized using a linear optimization and can be provided for use in modeling, OPC, defect inspection, defect prediction, or SMO.

### CROSS-REFERENCE TO RELATED APPLICATIONS

This application claims priority of PCT application PCT/CN2020/137957 which was filed on 21 Dec. 2020, and which is incorporated herein in its entirety by reference.

### TECHNICAL FIELD

The embodiments provided herein relate to computational lithography technology, and more specifically to unit cell extraction technology in computational lithography.

### BACKGROUND

In manufacturing processes of integrated circuits (ICs), computational lithography is utilized to improve yields from a design layout of an IC circuit. The ability to perform computational analysis of IC circuit layouts in computationally efficient ways is becoming increasingly important.

### SUMMARY

In some embodiments, a method of feature-based cell extraction comprises obtaining data representative of a layout, wherein the layout includes a pattern comprising oblique angle features, extracting unit cells from the pattern region comprising oblique angle features, identifying, using the unit cells, a set of regions of the layout matching the unit cells, and
generating, using the unit cells, a hierarchy for the set of regions. The method can include pattern regions comprising oblique angle features or comprising no vertices of features, determining a feature slope in the pattern region, determining a horizontal or a vertical pitch of structures in the pattern region, constructing a unit cell using the horizontal and vertical pitch, wherein the top and bottom boundaries of the unit cell are defined by the horizontal pitch, the left and right boundaries of the unit cell are defined by the vertical pitch, the location of the unit cell is based on the beginning point of the horizontal or vertical pitch. The method can further comprise, determining a line-space feature of structures in the pattern region, identifying the line-space feature, wherein identifying the line-space feature comprises, identifying segments crossing the pattern region, determining coordinates of locations where the segment intersects with structures on the layout, and determining an anchor point for the segment based on the line-space feature. The method can include constructing a unit cell using the line-space feature, wherein the top and bottom boundaries of the unit cell are defined by the line-space feature and the location of the unit cell is based on the anchor point for the segment. In some embodiments the method comprises storing, the unit cell in an associative data structure, wherein a key for the associative data structure is a feature of the pattern region. Identifying, using the unit cells, a set of regions of the layout matching the unit cells, can include identifying a feature of the pattern region, using the feature as a key, retrieving a unit cell from the associative data structure, and matching portions of the pattern region using the retrieved unit cell. In some embodiments the method includes optimizing the unit cell distribution on the set of regions using a linear optimization function wherein the linear optimization function optimizes the number of unit cells distributed across the set of regions such that the distribution in each region of the set of regions and optimizing the number of unit cells distributed across part of the region and maintaining block level symmetry for the remaining part of the region. The method can further comprise merging the extracted unit cells and removing duplicate unit cells. In some embodiments the hierarchy is in Graphic Database System (GDS) format, Graphic Database System II (GDS II) format, Open Artwork System Interchange Standard (OASIS) format, or Caltech Intermediate Format (CIF) and the hierarchy is provided for use in at least one of modeling, optical proximity correction (OPC), defect inspection, defect prediction, or source mask optimization (SMO).

In some embodiments a system comprising a memory storing a set of instructions and at least one processor configured to execute the set of instructions to cause the system to perform obtaining data representative of a layout, wherein the layout includes a pattern comprising oblique angle features or comprising no vertices of features, identifying, using the unit cells, a set of regions of the layout matching the unit cells, and generating, using the unit cells, a hierarchy for the set of regions. The at least one processor configured to execute the set of instructions can cause the system to further perform extracting unit cells is based on structures of the pattern region comprising oblique angle features, determining a feature slope in the pattern region, determining a horizontal or a vertical pitch of structures in the pattern region, constructing a unit cell using the horizontal and vertical pitch, wherein the top and bottom boundaries of the unit cell are defined by the horizontal pitch, the left and right boundaries of the unit cell are defined by the vertical pitch, the location of the unit cell is based on the beginning point of the horizontal or vertical pitch. The at least one processor configured to execute the set of instructions can cause the system to further perform determining a line-space feature of structures in the pattern region, identifying the line-space feature, wherein identifying the line-space feature comprises, identifying segments crossing the pattern region, determining coordinates of locations where the segment intersects with structures on the layout, and determining an anchor point for the segment based on the line-space feature. The at least one processor configured to execute the set of instructions can cause the system to further perform constructing a unit cell using the line-space feature, wherein the top and bottom boundaries of the unit cell are defined by the line-space feature and the location of the unit cell is based on the anchor point for the segment. In some embodiments The at least one processor configured to execute the set of instructions can cause the system to further perform storing, the unit cell in an associative data structure, wherein a key for the associative data structure is a feature of the pattern region. Identifying, using the unit cells, a set of regions of the layout matching the unit cells, can include identifying a feature of the pattern region, using the feature as a key, retrieving a unit cell from the associative data structure, and matching portions of the pattern region using the retrieved unit cell. In some embodiments The at least one processor configured to execute the set of instructions can cause the system to further perform optimizing the unit cell distribution on the set of regions using a linear optimization function wherein the linear optimization function maximizes the number of unit cells distributed across the set of regions such that the distribution in each region of the set of regions and optimizing the number of unit cells distributed across part of the region and maintaining block level symmetry for the remaining part of the region. The at least one processor configured to execute the set of instructions can cause the system to further perform merging the extracted unit cells and removing duplicate unit cells. In some embodiments the hierarchy is in Graphic Database System (GDS) format, Graphic Database System II (GDS II) format, Open Artwork System Interchange Standard (OASIS) format, or Caltech Intermediate Format (CIF) and the hierarchy is provided for use in at least one of modeling, optical proximity correction (OPC), defect inspection, defect prediction, or source mask optimization (SMO).

In some embodiments, a non-transitory computer readable medium that stores a set of instructions that is executable by at least one processor of a computing device can cause the computing device to perform a method of feature extraction for identifying a pattern, the method comprising obtaining data representative of a layout, wherein the layout includes a pattern comprising oblique angle features or no vertices of features, identifying, using the unit cells, a set of regions of the layout matching the unit cells, and generating, using the unit cells, a hierarchy for the set of regions. The method can include extracting unit cells is based on structures of the pattern region comprising oblique angle features, determining a feature slope in the pattern region, determining a horizontal or sa vertical pitch of structures in the pattern region, constructing a unit cell using the horizontal and vertical pitch, wherein the top and bottom boundaries of the unit cell are defined by the horizontal pitch, the left and right boundaries of the unit cell are defined by the vertical pitch, the location of the unit cell is based on the beginning point of the horizontal or vertical pitch. The method can further comprise, determining a line-space feature of structures in the pattern region, identifying the line-space feature, wherein identifying the line-space feature comprises, identifying segments crossing the pattern region, determining coordinates of locations where the segment intersects with structures on the layout, and determining an anchor point for the segment based on the line-space feature. The method can include constructing a unit cell using the line-space feature, wherein the top and bottom boundaries of the unit cell are defined by the line-space feature and the location of the unit cell is based on the anchor point for the segment. In some embodiments the method comprises storing, the unit cell in an associative data structure, wherein a key for the associative data structure is a feature of the pattern region. Identifying, using the unit cells, a set of regions of the layout matching the unit cells, can include identifying a feature of the pattern region, using the feature as a key, retrieving a unit cell from the associative data structure, and matching portions of the pattern region using the retrieved unit cell. In some embodiments the method includes optimizing the unit cell distribution on the set of regions using a linear optimization function wherein the linear optimization function maximizes the number of unit cells distributed across the set of regions such that the distribution in each region of the set of regions and optimizing the number of unit cells distributed across part of the region and maintaining block level symmetry for the remaining part of the region. The method can further comprise merging the extracted unit cells and removing duplicate unit cells. In some embodiments the hierarchy is in Graphic Database System (GDS) format, Graphic Database System II (GDS II) format, Open Artwork System Interchange Standard (OASIS) format, or Caltech Intermediate Format (CIF) and the hierarchy is provided for use in at least one of modeling, optical proximity correction (OPC), defect inspection, defect prediction, or source mask optimization (SMO).

Other advantages of the embodiments of the present disclosure will become apparent from the following description taken in conjunction with the accompanying drawings wherein are set forth, by way of illustration and example, certain embodiments of the present invention.

### BRIEF DESCRIPTION OF FIGURES

FIG. 1 is a diagram of an exemplary lithographic projection apparatus, consistent with embodiments of the present disclosure.

FIG. 2 is a block diagram of an exemplary system for modelling or simulating parts of a patterning process, consistent with embodiments of the present disclosure.

FIG. 3 is a diagram of an exemplary layout, consistent with embodiments of the present disclosure.

FIG. 4 is block diagram of an exemplary cell extraction system, consistent with embodiments of the present disclosure.

FIGS. 5A-5D illustrates exemplary pattern features, consistent with embodiments of the present disclosure.

FIG. 6 illustrates exemplary features for a pattern region, consistent with embodiments of the present disclosure.

FIG. 7 illustrates an exemplary unit cell for a pattern region, consistent with embodiments of the present disclosure

FIG. 8 illustrates an exemplary patch cut for a layout, consistent with embodiments of the present disclosure.

FIG. 9 illustrates an exemplary layout optimization, consistent with embodiments of the present disclosure.

FIG. 10 illustrates exemplary areas of a pattern region, consistent with embodiments of the present disclosure.

FIG. 11 is a process flowchart representing an exemplary method for cell extraction for pattern regions, consistent with embodiments of the present disclosure.

FIG. 12 is a process flowchart representing an exemplary method for unit cell extraction, consistent with embodiments of the present disclosure.

FIG. 13 is a process flowchart representing an exemplary method for line-space determination, consistent with embodiments of the present disclosure.

FIG. 14 is a process flowchart representing an exemplary method for pattern searching, consistent with embodiments of the present disclosure.

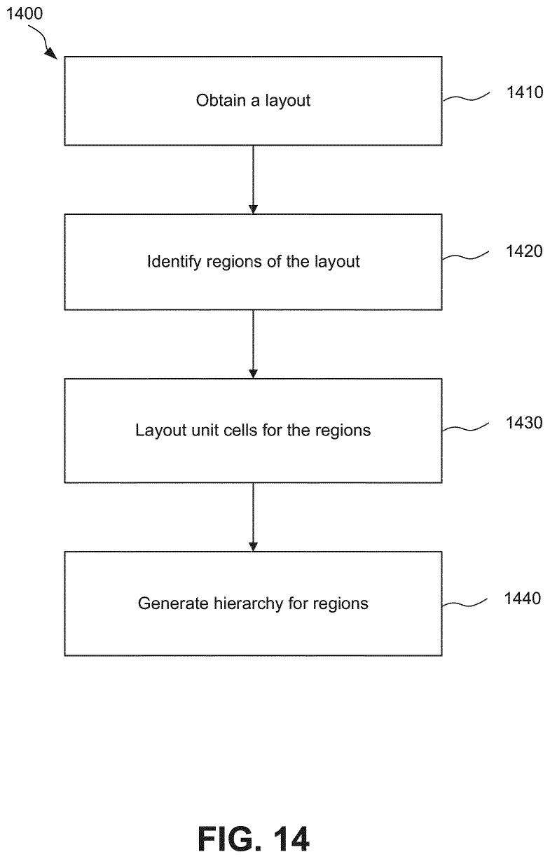

FIG. 15 is a process flowchart representing an exemplary method for creating a block hierarchy, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations. Instead, they are merely examples of apparatuses and methods consistent with aspects related to the disclosed embodiments as recited in the appended claims. For example, although some embodiments are described in the context of utilizing electron beams, the disclosure is not so limited. Other types of charged particle beams may be similarly applied. Furthermore, other imaging systems may be used, such as optical imaging, photo detection, x-ray detection, etc.

As the sizes of features and transistors continues to decrease, the ability to faithfully recreate a design layout on a substrate is becoming increasingly difficult. Manufacturing equipment can introduce artifacts or defects when trying to deposit such small features onto the substrate. To account for the physical difficulty of recreating IC layouts at such microscopic scales, IC manufactures rely on techniques such as computational lithography to analyze and modify a design to account for known artifacts of the physical manufacturing process. By adjusting the layout, mask, or other lithography data prior to manufacture to account for known manufacturing artifacts, IC manufacturers can better recreate the originally intended design.

In order to identify what pattern features may result in which physical artifacts, IC manufacturers must utilize enormous data sets to allow for accurate predictions. This can result in computationally expensive techniques that become increasingly complex as IC designs become increasingly complex.

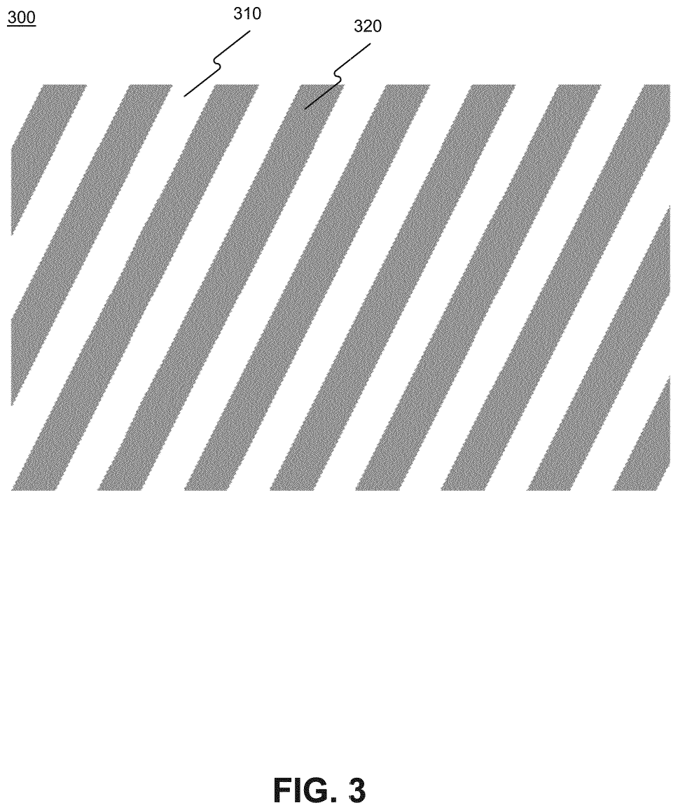

Because of this increased computational complexity and the need for enormous pattern data sets, techniques that can reduce the complexity are important. Because the same feature or group of features may repeat throughout an IC design, effective identification, classification, and selection of those patterns and features can drastically reduce the amount of computation necessary to correct an IC design. To be effective, repeating patterns must be easy to identify, classify, and process. Not all pattern shapes, however, are easily identifiable. In particular, some techniques often rely on distinct vertices, edges, and edge angles to classify and identify features or groups of features. But these techniques are not as effective for pattern features that have no vertices or oblique edge angles. These types of structures are often found in memory (for example, as shown in FIG. 3), such as DRAM (Dynamic Random Access Memory) that can occupy large portions of an IC layout.

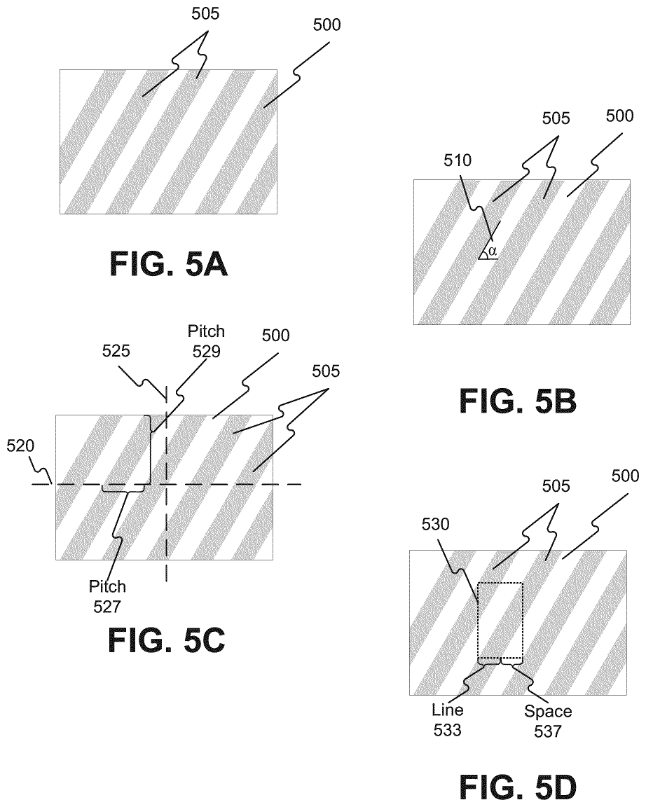

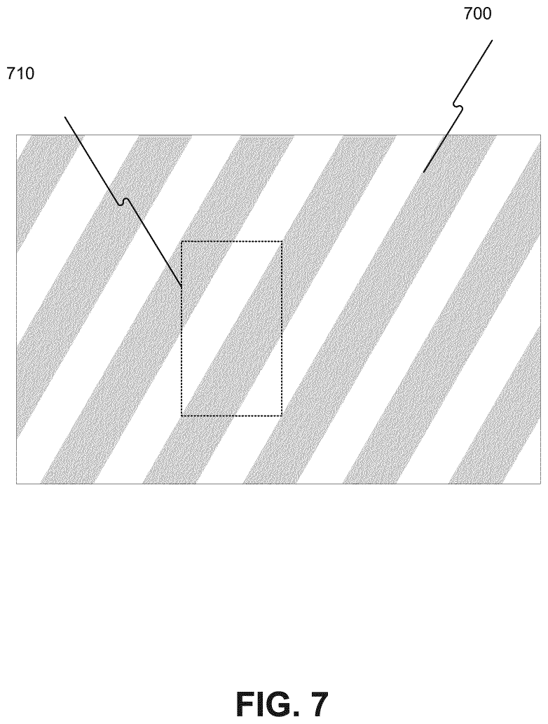

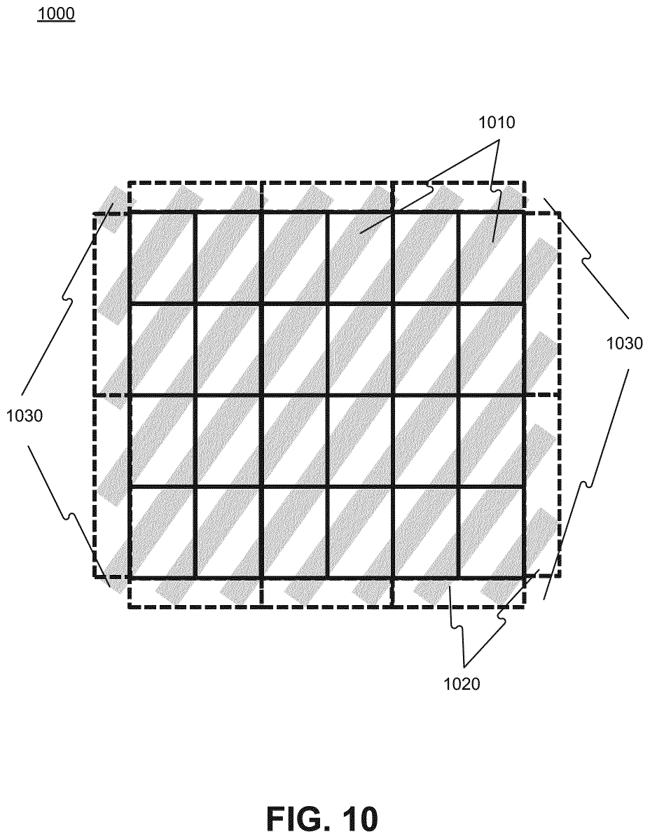

According to embodiments of the present disclosure, identification of these types of features can be improved by identifying pattern features (e.g., features shown in FIGS. 5B-5D) that are common to different memory areas of an IC layout. These features can be used to generate unit cells (e.g., as shown in FIG. 7) that can be repeated to create arrays covering the memory regions of an IC layout (for example, as shown in FIG. 10). By identifying these repeating cells of memory regions, the processing of a single cell can be applied to the larger region reducing the overall complexity of correcting an IC layout.

Many downstream applications can utilize the pattern identification and classification consistent with the embodiments described herein, including machine learning based modeling or optical proximity correction (OPC), machine learning based defect inspection and prediction, source mask optimization (SMO) or any other technologies that can select representative patterns for reducing runtime and improving pattern coverage. Some applications intend to reduce the cycle time during standard iteration flow, which may benefit from this invention by applying a representative pattern set instead of full chip in some non-critical cycles. Although embodiments disclosed herein may be disclosed in relation to OPC, SMO, or other specific techniques, the disclosure is not intended to limit the embodiments to those specific applications.

One way to help improve the design pattern layout processing accuracy and quality as well as turn-around time is to perform OPC in a hierarchical mode wherein a hierarchy of pattern features (e.g., the GDS hierarchy) in association with the design pattern layout is used to “re-paste” a previously computed OPC result or recipe a plurality of times. That is, prior to the “re-pasting”, a certain set of pattern features of a design pattern layout can have been processed with one or more optical proximity corrections to obtain an OPC result for that set of pattern features or can have been analyzed to identify specific features for modification or addition by an OPC process to obtain an OPC recipe. The design pattern layout hierarchy can then be scanned for the occurrences of that set of pattern features and then, for each occurrence, the OPC result for that set of pattern features can be inserted into the design pattern layout or the OPC recipe. Thus, the efficiency of OPC processing can be improved because OPC processing does not need to be performed for all the pattern features. Re-using a previously calculated OPC result or recipe can significantly reduce or eliminate having to perform OPC for the repeated features. Furthermore, because only one instance of a set of pattern regions needs to be analyzed, the accuracy of the analysis can be improved (e.g., by taking a longer time than would otherwise be available). Additionally or alternatively, consistency may be achieved as the “re-pasting” can avoid inconsistent results if the same set of pattern features would yield different optimal proximity corrections. So, advanced OPC can be used while keeping total runtime within specification. Moreover, it can enable more consistent OPC.

Relative dimensions of components in drawings may be exaggerated for clarity. Within the following description of drawings, the same or like reference numbers refer to the same or like components or entities, and only the differences with respect to the individual embodiments are described. As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

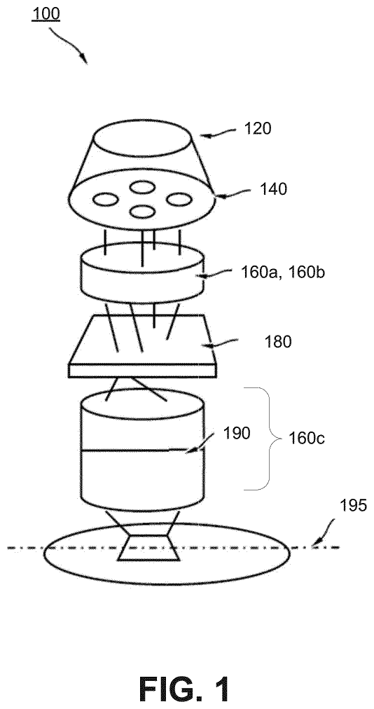

FIG. 1 illustrates an exemplary lithographic projection apparatus 100. Major components can include a radiation source 120, which can be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 140, 160a and 160b that shape radiation from the source 120; a patterning device 180; and transmission optics 160c that project an image of the patterning device pattern onto a substrate plane 195. An adjustable filter or aperture 190 at the pupil plane of the projection optics can restrict the range of beam angles that impinge on the substrate plane 195, where the largest possible angle defines the numerical aperture of the projection optics NA=n sin(Θmax), wherein n is the refractive index of the media between the substrate and the last element of the projection optics, and Θmax is the largest angle of the beam exiting from the projection optics that can still impinge on the substrate plane 195.

In a lithographic projection apparatus, a source provides illumination (i.e., radiation) to a patterning device and projection optics direct and shape the illumination, via the patterning device, onto a substrate. The projection optics may include at least some of the components 140, 160a, 160b and 160c. An aerial image (AI) is the radiation intensity distribution at substrate level. A resist model can be used to calculate the resist image from the aerial image. The resist model is related only to properties of the resist layer (e.g., effects of chemical processes which occur during exposure, post-exposure bake (PEB) and development). Optical properties of the lithographic projection apparatus (e.g., properties of the illumination, the patterning device, and the projection optics) dictate the aerial image and can be defined in an optical model. Since the patterning device used in the lithographic projection apparatus can be changed, it is desirable to separate the optical properties of the patterning device from the optical properties of the rest of the lithographic projection apparatus including at least the source and the projection optics. Details of techniques and models used to transform a design layout into various lithographic images (e.g., an aerial image, a resist image, etc.), apply OPC using those techniques and models and evaluate performance (e.g., in terms of process window) are described in U.S. Patent Application Publication Nos. US 2008-0301620, 2007-0050749, 2007-0031745, 2008-0309897, 2010-0162197, and 2010-0180251, the disclosure of each of which is hereby incorporated by reference in its entirety.

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as critical dimension (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means.
a programmable LCD array. An example of such a construction is given in U.S. Pat. No. 5,229,872, which is incorporated herein by reference.

One aspect of understanding a lithographic process is understanding the interaction of the radiation and the patterning device. The electromagnetic field of the radiation after the radiation passes the patterning device may be determined from the electromagnetic field of the radiation before the radiation reaches the patterning device and a function that characterizes the interaction. This function may be referred to as the mask transmission function (which can be used to describe the interaction by a transmissive patterning device and/or a reflective patterning device).

Variables of a patterning process are called “processing variables.” The patterning process may include processes upstream and downstream to the actual transfer of the pattern in a lithography apparatus. A first category can be variables of the lithography apparatus or any other apparatuses used in the lithography process. Examples of this category include variables of the illumination, projection system, substrate stage, etc. of a lithography apparatus. A second category may be variables of one or more procedures performed in the patterning process. Examples of this category include focus control or focus measurement, dose control or dose measurement, bandwidth, exposure duration, development temperature, chemical composition used in development, etc. A third category may be variables of the design layout and its implementation in, or using, a patterning device. Examples of this category can include shapes and/or locations of assist features, adjustments applied by a resolution enhancement technique (RET), CD of mask features, etc. A fourth category can be variables of the substrate. Examples include characteristics of structures under a resist layer, chemical composition and/or physical dimension of the resist layer, etc. A fifth category can be characteristics of temporal variation of one or more variables of the patterning process. Examples of this category include a characteristic of high frequency stage movement (e.g., frequency, amplitude, etc.), high frequency laser bandwidth change (e.g., frequency, amplitude, etc.) and/or high frequency laser wavelength change. These high frequency changes or movements are those above the response time of mechanisms to adjust the underlying variables (e.g., stage position, laser intensity). A sixth category can be characteristics of processes upstream of, or downstream to, pattern transfer in a lithographic apparatus, such as spin coating, post-exposure bake (PEB), development, etching, deposition, doping and/or packaging.

As will be appreciated, many, if not all of these variables, will have an effect on a parameter of the patterning process and often a parameter of interest. Non-limiting examples of parameters of the patterning process may include critical dimension (CD), critical dimension uniformity (CDU), focus, overlay, edge position or placement, sidewall angle, pattern shift, etc. Often, these parameters express an error from a nominal value (e.g., a design value, an average value, etc.). The parameter values may be the values of a characteristic of individual patterns or a statistic (e.g., average, variance, etc.) of the characteristic of a group of patterns.

The values of some or all of the processing variables, or a parameter related thereto, may be determined by a suitable method. For example, the values may be determined from data obtained with various metrology tools (e.g., a substrate metrology tool). The values may be obtained from various sensors or systems of an apparatus in the patterning process (e.g., a sensor, such as a leveling sensor or alignment sensor, of a lithography apparatus, a control system (e.g., a substrate or patterning device table control system) of a lithography apparatus, a sensor in a track tool, etc.). The values may be from an operator of the patterning process.

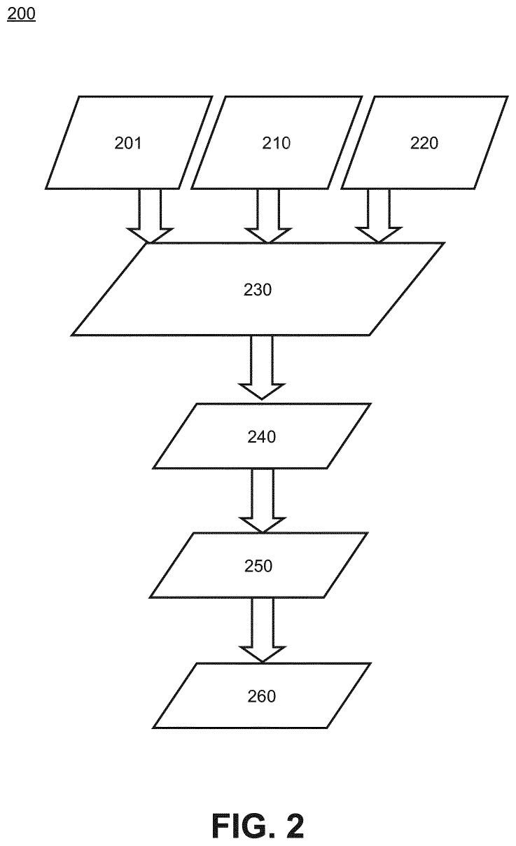

FIG. 2 is block diagram of an exemplary system 200 for modelling or simulating parts of a patterning process, consistent with embodiments of the present disclosure.

It is appreciated that the models used or created with system 200 can represent a different patterning process and need not comprise all the models described below. A source model 201 represents optical characteristics (including radiation intensity distribution, bandwidth and/or phase distribution) of the illumination of a patterning device. The source model 201 can represent the optical characteristics of the illumination that include, but not limited to, numerical aperture settings, illumination sigma (σ) settings as well as any particular illumination shape (e.g., off-axis radiation shape such as annular, quadrupole, dipole, etc.), where σ (or sigma) is outer radial extent of the illuminator.

A projection optics model 210 represents optical characteristics (including changes to the radiation intensity distribution or the phase distribution caused by the projection optics) of the projection optics. The projection optics model 210 can represent the optical characteristics of the projection optics, including aberration, distortion, one or more refractive indexes, one or more physical sizes, one or more physical dimensions, etc.

The patterning device/design layout model module 220 captures how the design features are laid out in the pattern of the patterning device and may include a representation of detailed physical properties of the patterning device, as described, for example, in U.S. Pat. No. 7,587,704, which is incorporated by reference in its entirety. In some embodiments, the patterning device/design layout model module 220 represents optical characteristics (including changes to the radiation intensity distribution or the phase distribution caused by a given design layout) of a design layout (e.g., a device design layout corresponding to a feature of an integrated circuit, a memory, an electronic device, etc.), which is the representation of an arrangement of features on or formed by the patterning device. Since the patterning device used in the lithographic projection apparatus can be changed, it is desirable to separate the optical properties of the patterning device from the optical properties of the rest of the lithographic projection apparatus including at least the illumination and the projection optics. The objective of the simulation is often to accurately predict, for example, edge placements and CDs, which can then be compared against the device design. The device design is generally defined as the pre-OPC patterning device layout and can be provided in a standardized digital file format such as GDS II or OASIS.

An aerial image 230 can be simulated from the source model 200, the projection optics model 210 and the patterning device/design layout model 220. An aerial image (AI) is the radiation intensity distribution at substrate level. Optical properties of the lithographic projection apparatus (e.g., properties of the illumination, the patterning device, and the projection optics) dictate the aerial image.

A resist layer on a substrate is exposed by the aerial image and the aerial image is transferred to the resist layer as a latent “resist image” (RI) therein. The resist image (RI) can be defined as a spatial distribution of solubility of the resist in the resist layer. A resist image 250 can be simulated from the aerial image 230 using a resist model 240. The resist model can be used to calculate the resist image from the aerial image, an example of which can be found in U.S. Pat. No. 8,200,468, the disclosure of which is hereby incorporated by reference in its entirety. The resist model typically describes the effects of chemical processes which occur during resist exposure, post exposure bake (PEB) and development, in order to predict, for example, contours of resist features formed on the substrate and so it typically related only to such properties of the resist layer (e.g., effects of chemical processes which occur during exposure, post-exposure bake and development). In some embodiments, the optical properties of the resist layer, e.g., refractive index, film thickness, propagation, and polarization effects—may be captured as part of the projection optics model 210.

The connection between the optical and the resist model is a simulated aerial image intensity within the resist layer, which arises from the projection of radiation onto the substrate, refraction at the resist interface and multiple reflections in the resist film stack. The radiation intensity distribution (aerial image intensity) is turned into a latent “resist image” by absorption of incident energy, which is further modified by diffusion processes and various loading effects. Efficient simulation methods that are fast enough for full-chip applications approximate the realistic 3-dimensional intensity distribution in the resist stack by a 2-dimensional aerial (and resist) image.

In some embodiments, the resist image can be used an input to a post-pattern transfer process model module 260. The post-pattern transfer process model 260 defines performance of one or more post-resist development processes (e.g., etch, development, etc.).

Simulation of the patterning process can, for example, predict contours, CDs, edge placement (e.g., edge placement error), etc. in the resist or etched image. Thus, the objective of the simulation is to accurately predict, for example, edge placement, aerial image intensity slope, or CD, etc. of the printed pattern. These values can be compared against an intended design to, e.g., correct the patterning process, identify where a defect is predicted to occur, etc. The intended design is generally defined as a pre-OPC design layout which can be provided in a standardized digital file format such as GDS II or OASIS or other file format.

Thus, the model formulation describes most, if not all, of the known physics and chemistry of the overall process, and each of the model parameters desirably corresponds to a distinct physical or chemical effect. The model formulation thus sets an upper bound on how well the model can be used to simulate the overall manufacturing process. In order to effectively model the manufacturing process, system 200 can make use of efficient process, such as those disclosed herein, for pattern selection, categorization, and classification. Embodiments described below can provide improved hierarchies for pattern instances for use with computational lithography models described in relation to FIG. 2.

FIG. 3 is a diagram of an exemplary design layout 300. Layout 300 can represent features that are consistent with DRAM integrated circuits. For the purposes of illustration, patterns similar to those shown in layout 300 can be referred to as DRAM regions or DRAM patterns. It is appreciated that the disclosure is not limited to DRAM integrated circuits or patterns and the use of the term “DRAM” in this disclosure is exemplary only and is not intended to limit the disclosure to only DRAM circuits. For example, any pattern feature or layouts exhibiting similar characteristics to that shown in layout 300 can be used. In particular, this includes patterns that have features with no vertexes.

In some embodiments, layout 300 can represent the entirety of an IC layout. In other embodiments layout 300 can represent a portion of a larger layout or design. As shown in FIG. 3, layout 300 can include feature areas 320 and non-feature areas 310. As shown, features 320 can include evenly spaced groupings of features in an angled, repeating pattern. A characteristic of this structure can be that the feature lines do not include distinct vertices or non-oblique angles. Embodiments consistent with the present disclosure can identify regions of a layout with these features, (e.g., layout 300) and process those regions.

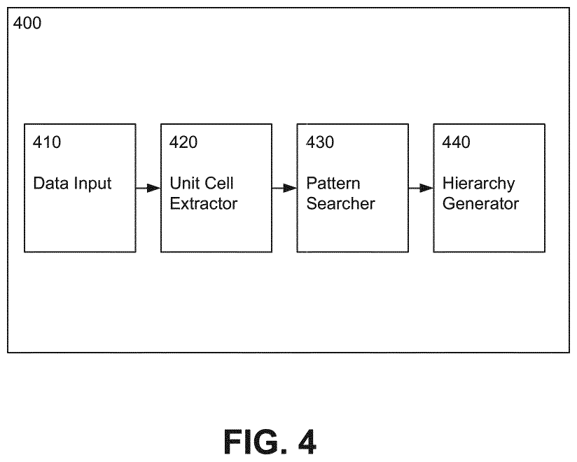

FIG. 4 is an exemplary block diagram for a cell extraction system 400, consistent with embodiments of the present disclosure. Cell extraction system 400 can operate on, for example, patterns similar to that shown in layout 300 of FIG. 3. It is appreciated that in various embodiments, system 400 may be part of a patterning, modeling, or computational lithography system (e.g., system 200 from FIG. 2), or other photolithography systems. In some embodiments, system 400 may be part of, for example, patterning device/design layout model 220, part of other modules of FIGS. 1 and 2, implemented as part of a photolithography system, as a stand-alone apparatus or computer module, or as part of an electronic design automation system.

As illustrated in FIG. 4, system 400 can include data input 410, cell extractor 420, pattern searcher 430, and hierarchy generator 440. Data input 410 can obtain pattern information representing all or a portion of an IC design layout used in, for example, system 200 of FIG. 2. According to embodiments of the present disclosure, data input 410 can include, among other things, a data stream stored in a Graphic Database System (GDS) format, Graphic Database System II (GDS II) format, an Open Artwork System Interchange Standard (OASIS) format, a Caltech Intermediate Format (CIF), etc. The wafer design layout may include the patterns for inclusion on the wafer. The pattern information may be mask patterns used to transfer features from the photolithography masks or reticles to a wafer. In some embodiments, a pattern in GDS or OASIS format, among others, may comprise feature information stored in a binary file format representing planar geometric shapes, text, and other information related to wafer design layout. In some embodiments, the pattern information can be layout 300 of FIG. 3, include layout 300, or include regions with similar feature characteristics as layout 300. For example, data input 410 can include DRAM regions.

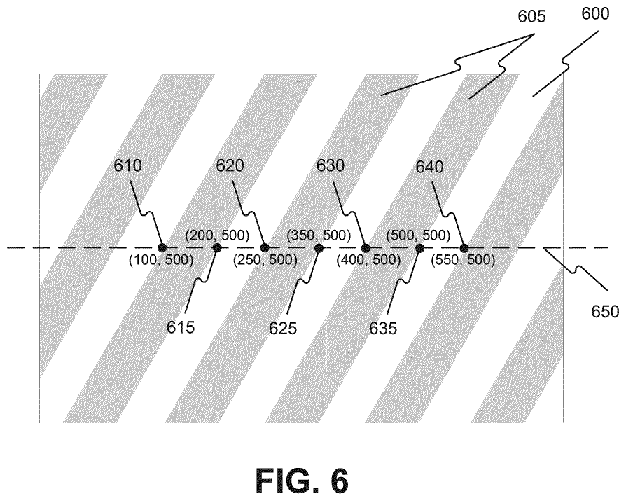

Data input 410 can provide the data stream to unit cell extractor 420. Unit cell extractor 420 can process the input data, identify areas of the pattern having specific pattern features, e.g., DRAM regions of the data stream, and generate unit cells for matching the same pattern throughout the input data stream, input pattern, or input layout. Exemplary pattern features that can be identified by unit cell extractor 420 are shown in FIGS. 5A-5D, described in more detail below. FIGS. 6 and 7, described in more detail below demonstrate exemplary unit cell creation by unit cell extractor 420. While the below disclosure in relation to FIGS. 5A-5D, 6, and 7 is described in relation to the operation of system 400 and components of system 400 (e.g., unit cell extractor 420), it is appreciated that the same functionality could be implemented by other components of system 400 or other systems. The description in relation to unit cell extractor 420 and system 400 is intended to be exemplary.

Referring to FIG. 5A, FIG. 5A is an exemplary pattern region 500 consistent with embodiments of the present disclosure. Pattern region 500 can be the same as layout 300 in FIG. 3. In some embodiments, pattern region 500 can be a region inside layout 300. In some embodiments, pattern region 500 can represent a DRAM region of an IC layout or design. FIGS. 5B-5C can show pattern features that can be identified in region 500. Pattern region 500 can include feature 505. Referring to FIG. 5B, FIG. 5B illustrates an exemplary pattern feature 510 of region 500.

Pattern feature 510 can be identified, for example, by unit cell extractor 420 in FIG. 4. As shown in FIG. 5B, angle 510 can be an angle, a, representing a feature slope for the features in pattern region 500. The feature slope can calculated by determining the distance in the horizontal, x, direction and the distance in the vertical, y, direction covered by a segment of the feature. The feature slope can thus be the change in the x direction divided by the change in the y direction and can be written as, for example, (“dx, dy”). Angle 510, a, can then be determined from the feature slope.

Referring to FIG. 5C, FIG. 5C illustrates exemplary pattern features 527 and 529 of pattern region 500. Pattern region 500 can be subdivided horizontally by segment 520 and vertically by segment 525. Using this information, the pitch of features 505 can be determined. For example, by examining where segments 520 and 525 intersect features 505, unit cell extractor 420 can identify pitch 527. Pitch 527 can represent the distance, along a segment, e.g., segment 520, between the start point of two of features 505 along the segment on pattern region 500. Pitch 527 can be the horizontal pitch of pattern region 500. Additionally, pitch 529 can represent the pitch of pattern region 500 in the vertical direction along a segment, e.g., segment 525. Like pitch 527, pitch 529 can represent the distance between the edges of two of features 505.

Referring to FIG. 5D, FIG. 5D illustrates exemplary pattern features 530, 533, and 537 of pattern region 500. Line 533 can represent the width of a pattern feature 505. Space 537 can represent the width of the space following a feature 505 before another pattern feature 505 begins. Together the feature can be referred to as a line-space feature of pattern region 500. In some embodiments, the line-space feature (e.g., from combining line 533 and space 537) can be equivalent to pitch 527 from FIG. 5C. Using some or all of the features, e.g., angle 510 of FIG. 5B, pitch 527 and pitch 529 of FIG. 5C, or line 533 and space 537 of FIG. 5D, a unit cell can be constructed. For example, referring back to FIG. 4, unit cell extractor 420 can generate unit cell 530 by extending the line-space feature created from line 533 and space 537 vertically along pitch 529 of, for example, FIG. 5C to create unit cell 530.

Referring to FIG. 6, FIG. 6 illustrates exemplary pattern features 610, 615, 620, 625, 630, 635, and 640 for pattern region 600 and features 605. Pattern features 610, 615, 620, 625, 630, 635, and 640 can represent border points along segment 650. Each of features 610, 615, 620, 625, 630, 635, and 640 can represent the start or end of a pattern feature 605 along segment 650. Unit cell extractor 420, for example, can use the coordinates associated with pattern features 610, 615, 620, 625, 630, 635, and 640 to calculate pattern features such as pitch 527 of FIG. 5C and line 533 and space 537 of FIG. 5D. For example, unit cell extractor 420 of FIG. 4, can determine that the difference in the x direction for pattern features 610 (with coordinates (100, 500)) and 615 (with coordinates (200, 500)) is 100 units. Because pattern feature 610 and 615 can represent the start and end of a feature 605 along segment 650, unit cell extractor 420 can determine the line feature (e.g., line 533 of FIG. 5D) is 100 units. Additionally, unit cell extractor 420 can determine that the space feature (e.g., space 537 of FIG. 5D) of features 605 is the difference between pattern feature 620 (with coordinates (250, 500)) and pattern feature 615 (with coordinates (200, 500)). In this example, unit cell extractor 420 can determine the space feature to be 50 units. Additionally, based on this analysis, unit cell extractor 420 can determine that the pitch of features 605 is 150 units by adding the calculated line feature of 100 units to the calculated space feature of 50 units. By analyzing the additional pattern features (e.g., pattern features 625, 630, 635, 640) unit cell extractor 420 can determine if the layout of features 605 is uniform. In some embodiments, if features 605 is uniform, the unit cell extractor 420 can determine that the pattern features uniformly repeat. In some embodiments, if the features 605 are determined to include not uniform features, then unit cell extractor 420 split segment 650 and calculate additional pattern features (e.g., line 533, space 537, and pitch 527).

Referring to FIG. 7, FIG. 7 illustrates an exemplary unit cell 710 for pattern region 700, consistent with embodiments of the present disclosure. Pattern region 700 can be the same as pattern region 600 in FIG. 6 and pattern region 500 in FIGS. 5A-5D. Using pattern features, e.g., pitch 527 of FIG. 5C and line 533 and space 537 of FIG. 5D, unit cell extractor 420 can identify unit cell 710 as representative of pattern region 700. In some embodiments, pattern region 700 includes uniform pattern features (as described in reference to FIG. 6 above). In these embodiments, the uniformity allows unit cell 710 to be moved around without changing the representation of the features within unit cell 710. For example, shifting unit cell 710 left or right by the pitch (e.g., pitch 527 from FIG. 5C) can result in a unit cell that is shifted but that includes the same pattern features. Shifting the unit cell by some other value can result in a pattern that represents the same features but is offset by the difference between the amount shifted and the pitch (e.g., pitch 527). Additionally, unit cell can be shifted along angle 510 from FIG. 5A, and the pattern represented by unit cell 710 can be the same even though unit cell 710 has shifted to a different location. Accordingly, unit cell 710 can be repeated multiple times within pattern 700 with each unit cell representing the same pattern. As a result, analysis of the portions of pattern 700 covered by the unit cells (e.g., unit cell 710) can be reduced to an analysis of a single unit cell 710. The results of the analysis can be applied to other portions of pattern region 700 covered by unit cell 710 without the need to duplicate the analysis.

Referring back to FIG. 4, unit cell extractor 420 can store the results of its analysis (e.g., angle 510, pitch 527, pitch 529, line 533, and space 537). For example, unit cell extractor 420 can store the features in hashmaps, and the unit cell extractor 420 can create various hashmaps to store, for example, the unit cell 530 of FIG. 5D, pitch 527 or 529 of FIG. 5C, line 533 and space 537 of FIG. 5D. In some embodiments, angle 510 of FIG. 5B can be used as the key for the various hashmaps.

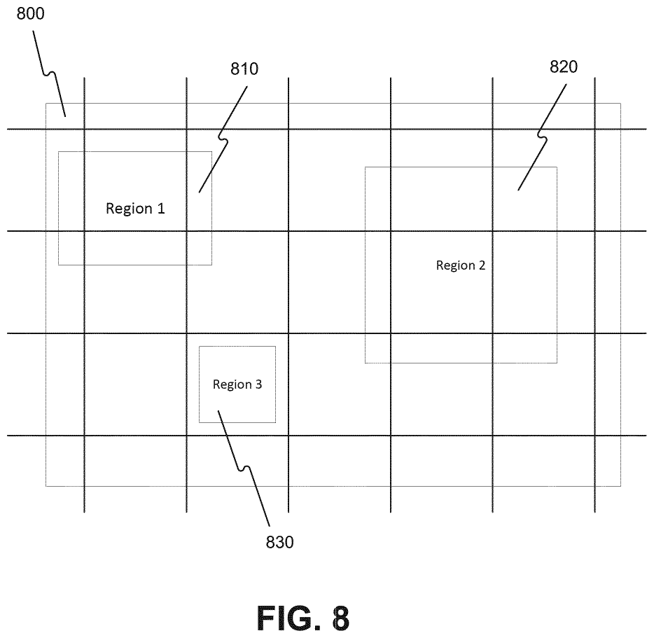

Pattern searcher 430 can use the stored hashmaps to search the layout or design for additional patterns. For example, the analysis of one DRAM region of a layout can be used to search for additional DRAM like regions of the layout. As pattern searcher 430 processes the layout, it can identify angles in the various DRAM areas of the pattern and use those angles to retrieve feature values from the various hashmaps. Processing the layout in this way can reduce the amount of processing necessary because processing of a single unit cell can be applied to multiple regions of the layout that match the unit cell. As described in relation to FIG. 8, pattern searcher 430 can identify multiple candidate pattern regions.

Referring to FIG. 8, FIG. 8 is an exemplary patch cut layout of a layout (e.g., layout 800). Pattern searcher 430 can search layout 800 and identify DRAM regions of the layout that require analysis. For example, pattern searcher 430 can identify region 810, region 820, and region 830 as DRAM regions of layout 800 based on characteristics of features in those regions. For example, pattern searcher 430 can identify regions that lack vertices or include features with only oblique angles as candidate regions.

Referring back to FIG. 4, pattern searcher 430 can process the layout to identify DRAM regions of the layout and provide those regions to hierarchy generator 440. For example, hierarchy generator 440 can process the regions of the layout identified by pattern searcher 430, apply the unit cells determined by unit cell extractor 420 and generate a new hierarchy for the identified regions of the layout. The hierarchy can be outputted in GDS, OASIS, or other relevant format for further processing by, for example, an OPC system or other computational lithography system.

In some embodiments, as shown in FIG. 8, regions identified by pattern searcher 430, (e.g., region 810, region 820) can be transected by patch cuts intended to split up the processing for a layout. In some embodiments, regions (e.g., region 830) may not be transected by patch cuts. For regions transected by patch cuts, hierarchy generator 440 can stitch together transected regions to allow processing of the entire region. By combining transected regions, hierarchy generator 440 can maximize the area across which unit cells can be applied. In these embodiments, hierarchy generator 440 can prevent duplicative processing where a patch cut might cross a unit cell boundary. Hierarchy generator 440 can then optimize the unit cell distribution across the regions (e.g., region 810, 820, and 830),

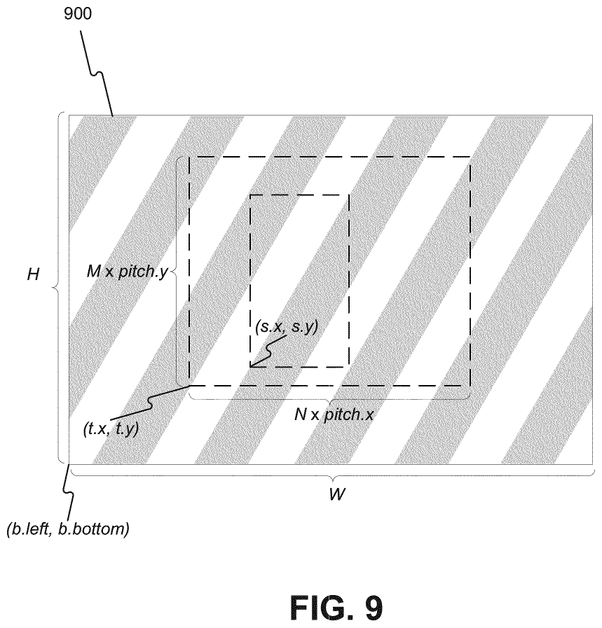

Referring to FIG. 9, FIG. 9 illustrates an exemplary layout optimization, consistent with embodiments of the present disclosure. In order to generate the most efficient hierarchy, hierarchy generator 440 can optimize the placement of unit cells in a DRAM pattern. Hierarchy generator 440 can place the unit cells on the DRAM pattern so that the unit cell placement can have block level symmetry. Block level symmetry can mean that after unit cells are placed on the DRAM pattern, eight different areas of the pattern will exist (as described in more detail in relation to FIG. 10.) These regions can include one region in the center of the DRAM pattern that can be composed of unit cells and eight additional areas comprising the top, bottom, left, right, and four corners of the layout. Block level symmetry can mean that the each of the eight additional areas are matched with their corresponding areas (e.g., the top area matches the bottom area, the right area matches the left area, and the four corners match) in orientation and dimension. Additionally, block-level symmetry can mean that the eight additional areas can be rotated, mirrored, or otherwise manipulated to derive an additional eight patterns that can be matched with the corresponding additional patterns. The layout optimization 900 can enforce the block-level symmetry on the placement of unit cells on a DRAM pattern region and can optimize the coverage of unit-cells. Hierarchy generator 440 can analyze region 900 as a linear optimization equation. In order to maximize the coverage of region 900 by unit cells, hierarchy generator 440 can optimize the coverage area using the following set of equations for the various portions of FIG. 9:

t·x=s·x+n*dx

t·y=s·y+m*dy

W=N*pitch·x+2(t·x−b·left)

H=M*pitch·y+2(t·y−b·bottom)

In the above equations, “t·x” and “t·y” can represent the beginning coordinates (i.e., the bottom left coordinates) of the coverage area. As shown in FIG. 9. “s·x” and “s·y” can represent the beginning coordinates (i.e., the bottom left coordinates) of a unit cell. “dx” and “dy” can represent the slope of unit cell and can be referred to as the change in “x” and the change in “y.” “W” represents the width of the layout or pattern region being analyzed and “H” can represent the height of the layout or pattern region. The coordinates “b·left” and “b·bottom” can represent the beginning coordinates (i.e., the bottom left coordinates) of the layout or pattern region being analyzed. “pitch·x” and “pitch·y” represent the pitch of the unit cell, as described in relation to FIGS. 5C and 6 above, in the horizontal and vertical directions, respectively. Hierarchy generator 440 can use the equations and variables described above and seek a solution for {n, m} when maximizing {N, M}. By maximizing {N,M}, hierarchy generator 440 can ensure that the largest possible area is covered by unit cells which can minimize the computational complexity needed to process an entire DRAM pattern region.

Referring to FIG. 10, FIG. 10 illustrates exemplary areas 1010,1020, and 1030 of a layout 1000, consistent with embodiments of the present disclosure. Regions 1010 can represent uniform areas of layout 1000 that correspond to unit cells calculated by system 400. In some embodiments, layout 1000 is a single pattern region of an IC layout (e.g., region 810, region 820, and region 830 of FIG. 8). As described above, system 400 can identify unit cells that match repeating areas of a layout. Hierarchy generator 440 can replicate the unit cells across the layout 1000. In some embodiments, the portion of layout 1000 covered by areas 1010 can be determined after optimizing the placement of areas 110 as described above in reference to FIG. 9. The pattern created by areas 1010 can be viewed as a two-dimensional array of unit cells. Hierarchy generator 440 can also create one-dimensional arrays composed of areas 1020 to cover the area of layout 1000 above, below, left and right of areas 1010 that are not covered by areas 1010. In some embodiments, areas 1020 that include repeating features can be divided according to unit cells calculated for those specific areas of layout 1000. In some embodiments, the same method and system described herein can be used to calculate pattern features for areas 1020, including, for example, calculating an angle and pitch. In some embodiments, areas 1020 will include a vertical pitch and no horizontal pitch. In other embodiments, areas 1020 will include a horizontal pitch and no vertical pitch. In some embodiments, areas 1030 can be the corner portions of layout 1000 and can be additional one-dimensional arrays processed in the same manner as areas 1020. After calculating and distributing unit cells to cover areas 1010, areas 1020, and areas 1030, the hierarchy of layout 1000, including areas 1010, areas 1020, and areas 1030 can be outputted for additional processing by OPC systems, computational lithography systems, or other lithography processes or systems. The hierarchy can be output in various data formats including as, for example, a GDS or OASIS file.

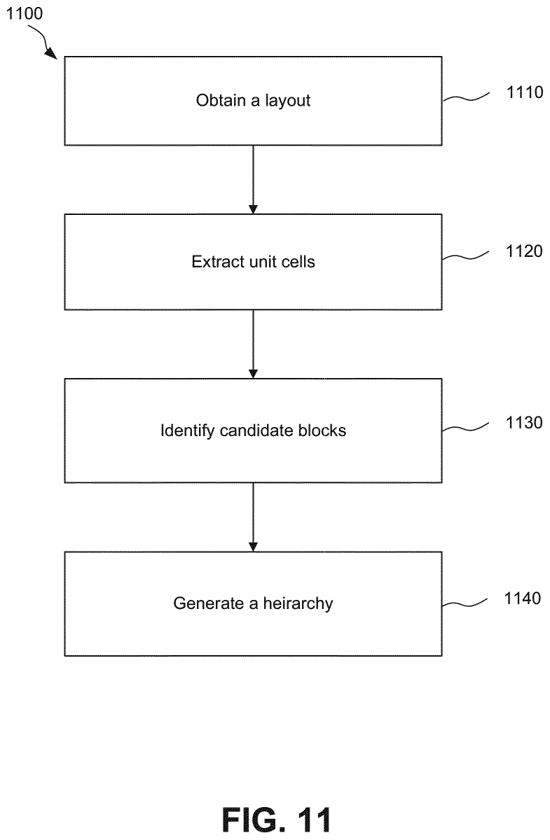

FIG. 11 is a process flowchart 1100 representing an exemplary method for cell extraction for pattern regions, consistent with embodiments of the present disclosure. The steps of method 1100 can be performed by, for example, system 400 of FIG. 4 executing on or otherwise using the features of a computing device, e.g., patterning device/design layout model 220 of FIG. 2, for purposes of illustration. It is appreciated that method 1100 can be altered to modify the order of steps and to include additional steps. Additionally, it is appreciated that the steps of method 1100 can be implemented in a distributed computing environment. For example, some steps of method 1100 or portions of steps of method 1100 can run in parallel on distributed computers and the results or output from those steps can be merged together to form a result. In some embodiments, such a distributed architecture can be referred to as a leaf-host architecture.

In step 1110, system 400 can obtain a layout (e.g., layout 300 of FIG. 3) or a portion of a layout. The layout can be an IC design or can be a portion of an IC design. In some embodiments the layout can include regions with characteristics of DRAM regions. These regions can, for example, include repeating features that do not have distinct vertices or non-oblique angles. The layout can include zero, one, or multiple DRAM regions (e.g., as shown in FIG. 8).

In step 1120, system 400 can extract unit cells (e.g., unit cell 710 of FIG. 7) that represent repeating portions of a DRAM region on the layout. System 400 can identify a unit cell by identifying features of the DRAM pattern regions. For example, system 400 can identify the slope angle, a (e.g., angle 510 of FIG. 5B), the pitch (e.g., pitch 527 and pitch 529 of FIG. 5C), and line-space features (e.g., line 533 and space 537 of FIG. 5C). System 400 can calculate the pitch and line-space features as described above in relation to FIG. 6. Based on those features, system 400 can create a unit cell (e.g., unit cell 710 of FIG. 7). In some embodiments, the unit cell can represent a repeatable block for the pattern region. System 400 can store the unit cell and features in various hash maps that can be used to match other areas of a layout.

In step 1130, system 400 can search a layout to identify candidate regions that appear to share characteristics of DRAM portions of a layout. System 400 can identify regions that include features with no vertices or regions that have features with oblique line angles as DRAM areas of the layout. In some embodiments, the information stored in hashmaps created as part of step 1120 can be retrieved and used to match areas that have the same features and pattern as the previously processed DRAM region. Using this process, system 400 can identify candidate DRAM regions of a layout (e.g., region 810, region 820, and region 830 of FIG. 8).

In step 1140, system 400 can generate a hierarchy of unit cells covering the DRAM regions of the layout. System 400 can process each of the DRAM candidate regions using the unit cells created in step 1120. For each region, system 400 can optimize the layout of unit cells on the DRAM region by treating the region as a linear optimization problem, e.g., as described in relation to FIG. 9). System 400 can maximize the number of unit cells that can be used for repeating portions of the DRAM region and create a two-dimensional array of unit cells (e.g., areas 1010 of FIG. 10). For the remaining portions of the DRAM region, system 400 can create unit cells that can be used to create one-dimensional arrays of unit cells to cover those areas (e.g., areas 1020 of FIG. 10). As a result, system 400 can divide DRAM portions of a layout with unit cells that represent repeating features. Because the features repeat, further processing can be done on one of the unit cells and the results can be applied to the additional unit cells without requiring high computational cost to process every portion of the DRAM region separately. In order to allow for the further processing, system 400 can generate a hierarchy that represents the cell array on the layout (e.g., as shown in FIG. 10). In some embodiments, system 400 can output the hierarchy as a GDS file, OASIS file, or similar data structure or format.

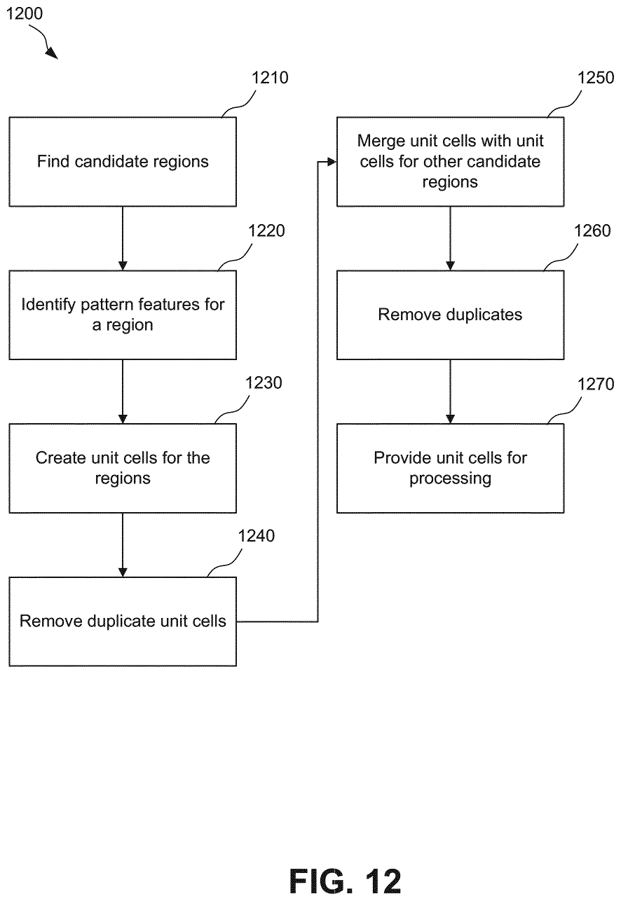

FIG. 12 is a process flowchart representing an exemplary method 1200 for unit cell extraction, consistent with embodiments of the present disclosure. The steps of method 1200 can be performed by, for example, system 400 of FIG. 4 executing on or otherwise using the features of a computing device, e.g., patterning device/design layout model 220 of FIG. 2 for purposes of illustration. It is appreciated that method 1200 can be altered to modify the order of steps and to include additional steps. Additionally, it is appreciated that the steps of method 1200 can be implemented in a distributed computing environment. For example, some steps of method 1200 or portions of steps of method 1200 can run in parallel on distributed computers and the results or output from those steps can be merged together to form a result. In some embodiments, such a distributed architecture can be referred to as a leaf-host architecture. In some embodiments, method 1200 can be used to implement step 1120 of method 1100

In step 1210, system 400 can be provided a layout (e.g., layout 300 of FIG. 3) or a portion of a layout. The layout can be an IC design or a portion of an IC design. In some embodiments, the layout can include regions with characteristics of DRAM regions. These regions can, for example, include repeating features that do not have distinct vertices or non-oblique angles. The layout can include zero, one, or multiple DRAM regions (e.g., as shown in FIG. 8). System 300 can identify a candidate region for processing as a DRAM region.

In step 1220, system 400 can identify pattern features of the DRAM candidate region. For example, system 400 can identify the slope angle, a (e.g., angle 510 of FIG. 5B), the pitch (e.g., pitch 527 and pitch 529 of FIG. 5C), and line-space features (e.g., line 533 and space 537 of FIG. 5C). System 400 can calculate the pitch and line-space features as described above in relation to FIG. 6. System 400 can store these features in various hash maps that can be used to match other areas of a layout.

In step 1230, system 400 can create unit cells (e.g., unit cell 710 of FIG. 7) that represent repeating portions of the DRAM candidate region of the layout. Using the features identified in step 1220, system 400 can create a unit cell (e.g., unit cell 710 of FIG. 7). In some embodiments, the unit cell can represent a repeatable block for the pattern region.

In step 1240, system 400 can remove duplicate unit cells. System 400 can generate multiple unit cells based on different candidate regions for pattern. In some instances, different pattern regions can result in the same unit cells. Because the same unit cell can be reused, system 400 can remove duplicate unit cells. Additionally, in some embodiments, different pattern regions can be processed by different processes or on distributed computing devices, which can be referred to as “leaf” nodes. In these embodiments, unit cells found by these “leaf” nodes can be provided to a “host” node. In these embodiments, the “host” node is responsible for removing duplicate unit cells that can be provided by different “leaf” nodes. These embodiments allow for processing of method 1200 to be split among distributed computer systems improving the efficiency of the processing.

In some embodiments, step 1210, step 1220, step 1230, and step 1240 can be performed on a leaf node in a distributed computing environment. In these embodiments, the leaf node can provide the output from step 1240 can be provided to a host for further processing. In these embodiments, the host node can perform the remaining steps of method 1200.

In step 1250, system 400 can merge unit cells found by different processes or from processing different sections of a candidate region into a combined data structure. The unit cells being merged can, in some embodiments, originate from different distributed processing systems, or in some embodiments, can originate from different portions of a candidate DRAM region.

In step 1260, system 400 can remove any remaining duplicates from the merged data structure. System 400 can, in step 1270, provide the remaining unit cells to other components or systems for further use.

In some embodiments, step 1250, step 1260, and step 1270 can be performed on a host node in a distributed computing environment. In these embodiments, the host node can receive input from a one or multiple leaf nodes (e.g., after step 1240) and can use that input for processing in step 1250, step 1260, and step 1270.

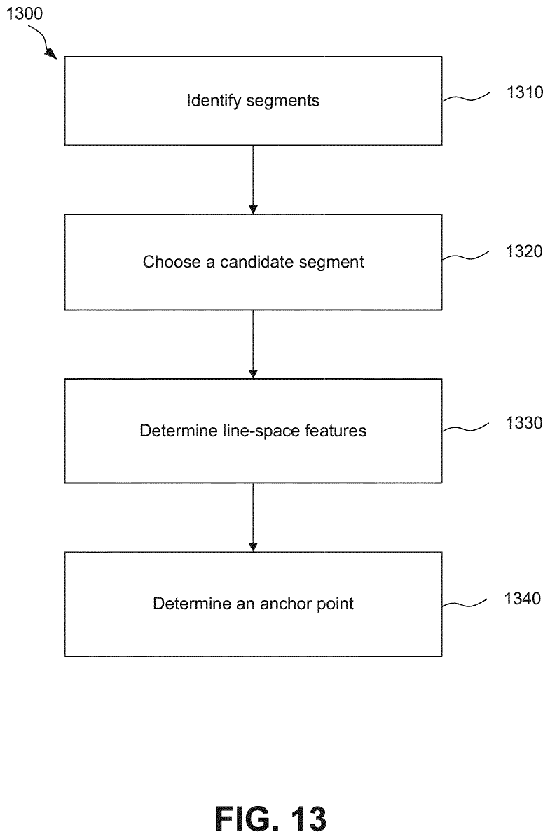

FIG. 13 is a process flowchart representing an exemplary method 1300 for line-space determination, consistent with embodiments of the present disclosure. The steps of method 1300 can be performed by, for example, system 400 of FIG. 4 executing on or otherwise using the features of a computing device, e.g., patterning device/design layout model 220 of FIG. 2 for purposes of illustration. It is appreciated that method 1300 can be altered to modify the order of steps and to include additional steps. Additionally, it is appreciated that the steps of method 1300 can be implemented in a distributed computing environment. For example, some steps of method 1300 or portions of steps of method 1300 can run in parallel on distributed computers and the results or output from those steps can be merged together to form a result. In some embodiments, such a distributed architecture can be referred to as a leaf-host architecture. In some embodiments, method 1300 can be used to implement portions of step 1220 of method 1200 and portions of step 1120 of method 1100.

In step 1310, system 400 can identify segments (e.g., segment 525 or segment 520 of FIG. 5C). System 400 can identify multiple candidate segments that transect a DRAM pattern region (e.g., region 600 of FIG. 6).

In step 1320, system 400 can choose, from the segments, a candidate segment (e.g., segment 650 of FIG. 6). The candidate segment can be chosen to maximize the length of the segment, minimize the pitch of the segment (e.g., pitch 527 of FIG. 5), and minimize the starting point of the segment. The starting point of the segment can be viewed as the first part of a segment that overlaps a pattern feature.

In step 1330, system 400 can determine line-space features (e.g., line 533 and space 537 of FIG. 5D) of the candidate segment. As described in relation to FIG. 6, system 400 can identify points on the candidate segment at the beginning or end of a pattern feature along the segment. Based on coordinates associated with each of these points, system 400 can determine the line-space feature. For example, as described in FIG. 6, system 400 can determine that the pitch of the line segment is 150 units (e.g., the difference between the x coordinates of features 620 and 610 of candidate segment 650 in FIG. 6).

In step 1340, after determining the line-space features of the candidate segment, system 400 can identify an anchor point for the candidate segment. The anchor point can be chosen to be the in the middle of the candidate segment shifted to begin at a line feature. The anchor point can be used to identify lines and pattern regions that have the same characteristics as the candidate line.

The steps of method 1400 can be performed by, for example, system 400 of FIG. 4 executing on or otherwise using the features of a computing device, e.g., patterning device/design layout model 220 of FIG. 2 for purposes of illustration. It is appreciated that method 1400 can be altered to modify the order of steps and to include additional steps. Additionally, it is appreciated that the steps of method 1400 can be implemented in a distributed computing environment. For example, some steps of method 1400 or portions of steps of method 1400 can run in parallel on distributed computers and the results or output from those steps can be merged together to form a result. In some embodiments, such a distributed architecture can be referred to as a leaf-host architecture. In some embodiments, method 1400 can be used to implement portions of step 1140 of method 1100.

In step 1410, system 400 can be provided a layout (e.g., layout 300 of FIG. 3) or a portion of a layout. The layout can be an IC design or can be a portion of an IC design. In some embodiments the layout can include regions with characteristics of DRAM regions.

In step 1420, system 400 can identify the regions of the layout that have DRAM characteristics. In some embodiments, system 400 can be provided with the regions (e.g., region 810, region 820, and region 830 of FIG. 8). In other embodiments, system 400 can search the layout and identify candidate regions

In step 1430, system 400 can layout unit cells (e.g., unit cells 710 of FIG. 7) on the DRAM regions. System 400 can analyze the dram regions and apply linear optimization techniques (e.g., linear optimization described in relation to FIG. 9) to the unit cell layout. The optimization can ensure that the maximum number of unit cells are placed on the DRAM regions. The unit cells can be used to create a two-dimensional array (e.g., areas 1010 of FIG. 10). System 400 can layout additionally calculate unit cells to cover the remaining portions of the DRAM region with a one-dimensional array of unit cells for the left, right, top, bottom, and corners of the region. In some embodiments, system 400 can skip unit cells for areas that have no features.

In step 1440, system 400 can process the unit cell layout (e.g., the unit cells for areas 1010 and 1020 shown in FIG. 10) and generate a hierarchy that represents the layout. The hierarchy can be generated in, for example, GDS II or OASIS format. These are exemplary and system 400 can use any data structure or file format that preserves the calculated hierarchy.

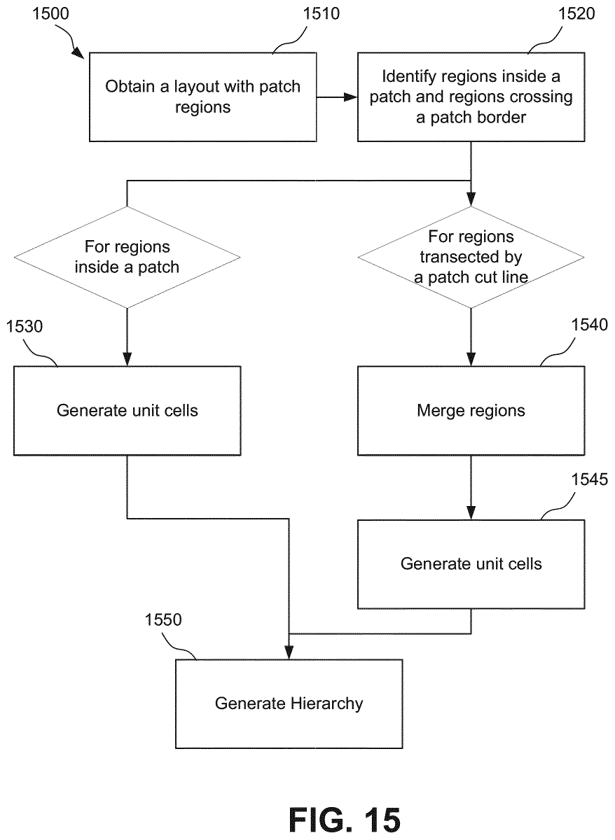

FIG. 15 is a process flowchart representing an exemplary method 1500 for creating a block hierarchy, consistent with embodiments of the present disclosure. The steps of method 1500 can be performed by, for example, system 400 of FIG. 4 executing on or otherwise using the features of a computing device, e.g., patterning device/design layout model 220 of FIG. 2 for purposes of illustration. It is appreciated that method 1500 can be altered to modify the order of steps and to include additional steps. Additionally, it is appreciated that the steps of method 1500 can be implemented in a distributed computing environment. For example, some steps of method 1500 or portions of steps of method 1500 can run in parallel on distributed computers and the results or output from those steps can be merged together to form a result. In some embodiments, such a distributed architecture can be referred to as a leaf-host architecture

In step 1510, system 400 can obtain a layout (e.g., layout 300 of FIG. 3) or a portion of a layout that has been separated or cut by patch lines into patch regions. The layout can be an IC design or can be a portion of an IC design. In some embodiments the layout can include identified candidate regions with characteristics of DRAM. In some

In step 1520, system 400 can use patch cut information (e.g., layout 800 of FIG. 8) for the layout to determine which regions (e.g., region 830 of FIG. 8) can be entirely within a patch cut region and which regions (e.g., region 810 and region 820 of FIG. 8) can be transected by patch cut lines. System 400 can provide the regions entirely in a patch cut (e.g., region 830) to step 1530 for further processing and can provide regions transected by a patch cut lines to step 1540 for further processing.

In some embodiments method 1500 can be implemented in a distributed computing environment including leaf and host nodes. In these embodiments, step 1520 can execute on a leaf node. In these embodiments, because the leaf node may not have access to every region of the layout, including regions existing on other sides of patch cut lines, regions transected by a patch cut line can be provided back to a host for processing in step 1540.

As stated above, for regions existing entirely within a patch, system 400 can proceed to step 1530. In step 1530, system 400 can process the regions and generate appropriate unit cells (e.g., as described in relation to FIGS. 5A-5D, 6, and 7 and as described in relation to method 1200 of FIG. 12). After generating unit cells for the provided region, system 400 can provide the unit cell information to step 1550 for additional processing. In some embodiments, step 1530 can be implemented in a leaf node of a distributed computing system. In these embodiments, the leaf node can provide the unit cells back to the host for additional processing.

As stated above, for regions transacted by a patch line, system 400 can proceed to step 1540. In step 1540, system 400 can identify the other portions of regions transected by the patch cut lines and merge adjoining regions into a single region. In some embodiments, where method 1500 is implemented in a distributed computing environment that includes a leaf-host architecture, step 1540 can be implemented on the host and can receive regions separated by patch cut lines from different leaf nodes. After merging the regions, in step 1540, system 400 can generate appropriate unit cells (e.g., as described in relation to FIGS. 5A-5D, 6, and 7 and as described in relation to method 1200 of FIG. 12). After generating unit cells for the provided region, system 400 can provide the unit cell information to step 1550 for additional processing.

In step 1550, system 400 can generate a hierarchy from the unit cell layout (e.g., areas 1010 and areas 1020 of FIG. 10) and output the hierarchy, for example, in GDS II or OASIS format. System 400 can generate the hierarchy as described in relation to FIG. 10, and method 1100 of FIG. 11).

A non-transitory computer readable medium may be provided that stores instructions for a processor of a controller (e.g., controller 50 of FIG. 1) or of a system (e.g., system 300 of FIG. 3) to carry out, among other things, image inspection, image acquisition, image transformation, image processing, image comparison, stage positioning, beam focusing, electric field adjustment, beam bending, condenser lens adjusting, activating charged-particle source, and beam deflecting. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

Embodiments of the present disclosure can be further described by the following clauses.

1. A method of feature-based cell extraction comprising:
obtaining data representative of a layout, wherein the layout includes a pattern comprising oblique angle features;
extracting unit cells from the pattern region comprising oblique angle features;
identifying, using the unit cells, a set of regions of the layout matching the unit cells; and
generating, using the unit cells, a hierarchy for the set of regions.

2. The method of clause 1, wherein the pattern region comprises oblique angle features.

3. The method of clauses 1 or 2, wherein the pattern region comprises no vertices of features.

4. The method of any of clauses 1-3, further comprising determining a feature slope in the pattern region.

5. The method of any of clauses 1-3, further comprising determining a horizontal or a vertical pitch of structures in the pattern region.

6. The method of clause 5, further comprising:
constructing a unit cell using the horizontal and vertical pitch, wherein:
   top and bottom boundaries of the unit cell are defined by the horizontal pitch;
   left and right boundaries of the unit cell are defined by the vertical pitch; and
   a location of the unit cell is based on a beginning point of the horizontal or vertical pitch.

7. The method of any of clauses 1-3, further comprising determining a line-space feature of structures in the pattern region.

8. The method of clause 7, further comprising identifying the line-space feature, wherein identifying the line-space feature comprises:
identifying segments crossing the pattern region;
determining coordinates of locations where the segment intersects with structures on the layout; and
determining an anchor point for the segment based on the line-space feature.

9. The method of clause 8, further comprising:
constructing a unit cell using the line-space feature, wherein:
   top and bottom boundaries of the unit cell are defined by the line-space feature; and
   a location of the unit cell is based on the anchor point for the segment.

10. The method of any of clauses 1-9, further comprising:
storing the unit cell in an associative data structure, wherein a key for the associative data structure is a feature of the pattern region.

11. The method of clause 10, wherein identifying, using the unit cells, a set of regions of the layout matching the unit cells, further comprises:
identifying a feature of the pattern region;
using the feature as a key, retrieving a unit cell from the associative data structure;
matching portions of the pattern region using the retrieved unit cell.

12. The method of any of clauses 1-11, further comprising optimizing the unit cell distribution on the set of regions using a linear optimization function.

13. The method of any of clause 12 wherein the linear optimization function comprises:
optimizing the number of unit cells distributed across the set of regions such that the distribution in each region of the set of regions comprises:
   optimizing the number of unit cells distributed across part of the region; and
   maintaining block level symmetry for the remaining part of the region.

14. The method of any one of clauses 1-13, wherein the method further comprises:
merging the extracted unit cells; and
removing duplicate unit cells.

15. The method of any of clauses 1-14, wherein the hierarchy is in Graphic Database System (GDS) format, Graphic Database System II (GDS II) format, Open Artwork System Interchange Standard (OASIS) format, or Caltech Intermediate Format (CIF).

16. The method of any one of clauses 1-15, wherein the hierarchy is provided for use in at least one of modeling, optical proximity correction (OPC), defect inspection, defect prediction, or source mask optimization (SMO).

17. A system comprising:
a memory storing a set of instructions; and
at least one processor configured to execute the set of instructions to cause the system to perform:
   obtaining data representative of a layout, wherein the layout includes a pattern comprising oblique angle features;
   extracting unit cells from the pattern region comprising oblique angle features;
   identifying, using the unit cells, a set of regions of the layout matching the unit cells; and
   generating, using the unit cells, a hierarchy for the set of regions.

18. The system of clause 17, wherein the pattern region comprises oblique angle features.

19. The system of clauses 17 or 18, wherein the pattern region comprises no vertices of features.

20. The system of any of clauses 17-19, wherein the at least one processor is configured to execute the set of instructions to cause the system to further perform determining a feature slope in the pattern region.

21. The system of any of clauses 17-19, wherein the at least one processor is configured to execute the set of instructions to cause the system to further perform determining a horizontal or a vertical pitch of structures in the pattern region.

22. The system of clause 21, wherein the at least one processor is configured to execute the set of instructions to cause the system to further perform:
constructing a unit cell using the horizontal and vertical pitch, wherein:
   top and bottom boundaries of the unit cell are defined by the horizontal pitch;
   left and right boundaries of the unit cell are defined by the vertical pitch; and
   a location of the unit cell is based on the beginning point of the horizontal or vertical pitch.

23. The system of any of clauses 17-19 wherein the at least one processor is configured to execute the set of instructions to cause the system to further perform determining a line-space feature of structures in the pattern region.

24. The system of clause 23, wherein the at least one processor is configured to execute the set of instructions to cause the system to further perform:
identifying segments crossing the pattern region;
determining coordinates of locations where the segment intersects with structures on the layout; and
determining an anchor point for the segment based on the line-space feature.

25. The system of clause 24, wherein the at least one processor is configured to execute the set of instructions to cause the system to further perform:
constructing a unit cell using the line-space feature, wherein:
   top and bottom boundaries of the unit cell are defined by the line-space feature; and
   a location of the unit cell is based on the anchor point for the segment.

26. The system of any of clauses 17-25, wherein the at least one processor is configured to execute the set of instructions to cause the system to further perform:
storing, the unit cell in an associative data structure, wherein a key for the associative data structure is a feature of the pattern region.

27. The system of any of clauses 26, wherein the at least one processor is configured to execute the set of instructions to cause the system to further perform:
identifying a feature of the pattern region;
using the feature as a key, retrieving a unit cell from the associative data structure;
matching portions of the pattern region using the retrieved unit cell.

28. The system of any of clauses 17-27, wherein the at least one processor is configured to execute the set of instructions to cause the system to further perform optimizing the unit cell distribution on the set of regions using a linear optimization function.

29. The system of clause 28, wherein the linear optimization function:
optimizes the number of unit cells distributed across the set of regions such that the distribution in each region of the set of regions comprises:
   optimizes the number of unit cells distributed across part of the region; and
   maintaining block level symmetry for the remaining part of the region.

30. The system of any of clauses 17-29, wherein the at least one processor is configured to execute the set of instructions to cause the system to further perform:
merging the extracted unit cells; and removing duplicate unit cells.

31. The system of any of clauses 17-30, wherein the hierarchy is in Graphic Database System (GDS) format, Graphic Database System II (GDS II) format, Open Artwork System Interchange Standard (OASIS) format, or Caltech Intermediate Format (CIF).

32. The system of any of clauses 17-31, wherein the hierarchy is provided for use in at least one of modeling, optical proximity correction (OPC), defect inspection, defect prediction, or source mask optimization (SMO).

33. A non-transitory computer readable medium that stores a set of instructions that is executable by at least one processor of a computing device to cause the computing device to perform a method of feature extraction for identifying a pattern, the method comprising:
obtaining data representative of a layout, wherein the layout includes a pattern comprising oblique angle features;
extracting unit cells from the pattern region comprising oblique angle features;
identifying, using the unit cells, a set of regions of the layout matching the unit cells; and
generating, using the unit cells, a hierarchy for the set of regions.

34. The non-transitory computer readable medium of clause 33, wherein the pattern region comprises oblique angle features.

35. The non-transitory computer readable medium of any of clauses 33 or 34, wherein the pattern region comprises no vertices of features.

36. The non-transitory computer readable medium of any of clauses 33-35 that store a set of instructions that is executable by at least one processor of a computing device to cause the computing device to further perform determining a feature slope in the pattern region.

37. The non-transitory computer readable medium of any of clauses 33-35 that store a set of instructions that is executable by at least one processor of a computing device to cause the computing device to further perform determining a horizontal or a vertical pitch of structures in the pattern region.

38. The non-transitory computer readable medium of clause 37 that store a set of instructions that is executable by at least one processor of a computing device to cause the computing device to further perform:
constructing a unit cell using the horizontal and vertical pitch, wherein:
   top and bottom boundaries of the unit cell are defined by the horizontal pitch;
   left and right boundaries of the unit cell are defined by the vertical pitch; and
   a location of the unit cell is based on the beginning point of the horizontal or vertical pitch.

39. The non-transitory computer readable medium of any of clauses 33-35 that store a set of instructions that is executable by at least one processor of a computing device to cause the computing device to further perform determining a line-space feature of structures in the pattern region.

40. The non-transitory computer readable medium of clause 39 that stores a set of instructions that is executable by at least one processor of a computing device to cause the computing device to further perform identifying the line-space feature, wherein identifying the line-space feature comprises:
identifying segments crossing the pattern region;
determining coordinates of locations where the segment intersects with structures on the layout; and
determining an anchor point for the segment based on the line-space feature.

41. The non-transitory computer readable medium of clause 40 that stores a set of instructions that is executable by at least one processor of a computing device to cause the computing device to further perform, further comprising:
constructing a unit cell using the line-space feature, wherein:
   top and bottom boundaries of the unit cell are defined by the line-space feature; and
   a location of the unit cell is based on the anchor point for the segment.

42. The non-transitory computer readable medium of any of clauses 33-41 that store a set of instructions that is executable by at least one processor of a computing device to cause the computing device to further perform, further comprising:
storing, the unit cell in an associative data structure, wherein a key for the associative data structure is a feature of the pattern region.

43. The non-transitory computer readable medium of clause 42 that stores a set of instructions that is executable by at least one processor of a computing device to cause the computing device to further perform, wherein identifying, using the unit cells, a set of regions of the layout matching the unit cells, further comprises:
identifying a feature of the pattern region;
using the feature as a key, retrieving a unit cell from the associative data structure;
matching portions of the pattern region using the retrieved unit cell.

44. The non-transitory computer readable medium of any of clauses 33-43 that store a set of instructions that is executable by at least one processor of a computing device to cause the computing device to further perform optimizing the unit cell distribution on the set of regions using a linear optimization function.

45. The non-transitory computer readable medium of clause 44, wherein the linear optimization function:
optimizing the number of unit cells distributed across the set of regions such that the distribution in each region of the set of regions comprises:
   optimizing the number of unit cells distributed across part of the region; and
   maintaining block level symmetry for the remaining part of the region.

46. The non-transitory computer readable medium of any of clauses 33-45 that store a set of instructions that is executable by at least one processor of a computing device to cause the computing device to further perform, wherein the method further comprises:
merging the extracted unit cells; and
removing duplicate unit cells.

47. The non-transitory computer readable medium of any of clauses 33-46, wherein the hierarchy is in Graphic Database System (GDS) format, Graphic Database System II (GDS II) format, Open Artwork System Interchange Standard (OASIS) format, or Caltech Intermediate Format (CIF).

48. The non-transitory computer readable medium of any of clauses 33-47, wherein the hierarchy is provided for use in at least one of modeling, optical proximity correction (OPC), defect inspection, defect prediction, or source mask optimization (SMO).

The block diagrams in the figures illustrate the architecture, functionality, and operation of possible implementations of systems, methods, and computer hardware/software products according to various exemplary embodiments of the present disclosure. In this regard, each block in a schematic diagram may represent certain arithmetical or logical operation processing that may be implemented using hardware such as an electronic circuit. Blocks may also represent a module, a segment, or a portion of code that comprises one or more executable instructions for implementing the specified logical functions. It should be understood that in some alternative implementations, functions indicated in a block may occur out of the order noted in the figures. For example, two blocks shown in succession may be executed or implemented substantially concurrently, or two blocks may sometimes be executed in reverse order, depending upon the functionality involved. Some blocks may also be omitted.

It will be appreciated that the embodiments of the present disclosure are not limited to the exact construction that has been described above and illustrated in the accompanying drawings, and that various modifications and changes may be made without departing from the scope thereof. The present disclosure has been described in connection with various embodiments, other embodiments of the invention will be apparent to those skilled in the art from consideration of the specification and practice of the invention disclosed herein. It is intended that the specification and examples be considered as exemplary only, with a true scope and spirit of the invention being indicated by the following claims.

The descriptions above are intended to be illustrative, not limiting. Thus, it will be apparent to one skilled in the art that modifications may be made as described without departing from the scope of the claims set out below.

1. A method of feature-based cell extraction, the method comprising:
obtaining data representative of a layout, wherein the layout includes a pattern comprising oblique angle features;
extracting unit cells from the pattern region comprising oblique angle features;
identifying, by a hardware computer system and using the unit cells, a set of regions of the layout matching the unit cells; and
generating, using the unit cells, a hierarchy for the set of regions.

2. The method of claim 1, wherein the pattern region comprises no vertices of features.

3. The method of claim 1, further comprising determining a feature slope in the pattern region.

4. The method of claim 1, further comprising determining a horizontal or vertical pitch of structures in the pattern region.

5. The method of claim 4, comprising determining the horizontal and vertical pitch and further comprising constructing a unit cell using the horizontal and vertical pitch, wherein:
top and bottom boundaries of the unit cell are defined by the horizontal pitch;
left and right boundaries of the unit cell are defined by the vertical pitch; and
a location of the unit cell is based on a beginning point of the horizontal or vertical pitch.

6. The method of claim 1, further comprising determining a line-space feature of structures in the pattern region.

7. The method of claim 6, further comprising identifying the line-space feature, wherein identifying the line-space feature comprises:
identifying a segment crossing the pattern region;
determining coordinates of locations where the segment intersects with structures on the layout; and
determining an anchor point for the segment based on the line-space feature.

8. The method of claim 7, further comprising constructing a unit cell using the line-space feature, wherein:
top and bottom boundaries of the unit cell are defined by the line-space feature; and
a location of the unit cell is based on the anchor point for the segment.

9. The method of claim 1, further comprising storing the unit cell in an associative data structure, wherein a key for the associative data structure is a feature of the pattern region.

10. The method of claim 9, wherein the identifying a set of regions further comprises:
identifying a feature of the pattern region;
retrieving, using the feature as a key, a unit cell from the associative data structure; and
matching portions of the pattern region using the retrieved unit cell.

11. The method of claim 1, further comprising optimizing the unit cell distribution on the set of regions using a linear optimization function.

12. The method of claim 11, wherein the linear optimization function comprises optimizing the number of unit cells distributed across the set of regions such that the distribution in each region of the set of regions comprises:
optimizing the number of unit cells distributed across part of the region; and
maintaining block level symmetry for the remaining part of the region.

13. The method of claim 1, further comprising:
merging the extracted unit cells; and
removing duplicate unit cells.

14. The method of claim 1, wherein the hierarchy is in Graphic Database System (GDS) format, Graphic Database System II (GDS II) format, Open Artwork System Interchange Standard (OASIS) format, or Caltech Intermediate Format (CIF).

15. The method of claim 1, wherein the hierarchy is provided for use in at least one selected from: modeling, optical proximity correction (OPC), defect inspection, defect prediction, or source mask optimization (SMO).

16. A non-transitory computer-readable medium that stores a set of instructions that is executable by at least one processor of a computing system to cause the computing system to at least:
obtain data representative of a layout, wherein the layout includes a pattern comprising oblique angle features;
extract unit cells from the pattern region comprising oblique angle features;
identify, using the unit cells, a set of regions of the layout matching the unit cells; and
generate, using the unit cells, a hierarchy for the set of regions.

17. The computer-readable medium of claim 16, wherein the pattern region comprises no vertices of features.

18. The computer-readable medium of claim 16, wherein the instructions are further configured to cause the computing system to determine a feature slope in the pattern region.

19. The computer-readable medium of claim 16, wherein the instructions are further configured to cause the computing system to determine a horizontal or vertical pitch of structures in the pattern region.

20. The computer-readable medium of claim 16, wherein the instructions are further configured to cause the computing system to determine a line-space feature of structures in the pattern region.
